(19) United States
(12) Patent Application Publication
(10) Pub. No.: US 2022/0013699 A1
(43) Pub. Date: Jan. 13, 2022

(54) METHOD OF PRODUCING A PLURALITY OF RADIATION-EMITTING COMPONENTS, RADIATION-EMITTING COMPONENT, METHOD OF PRODUCING A CONNECTION CARRIER, AND CONNECTION CARRIER

(71) Applicant: OSRAM Opto Semiconductors GmbH, Regensburg (DE)

(72) Inventors: Sebastian Wittmann, Regenstauf (DE); Korbinian Perzlmaler, Regensburg (DE)

(21) Appl. No.: 17/294,090

(22) PCT Filed: Nov. 11, 2019
(86) PCT No.: PCT/EP2019/080873

§ 371 Date: May 14, 2021

(30) Foreign Application Priority Data
Nov. 14, 2018 (DE) 10 2018 128 570.1

(51) Int. Cl. H01L 33/62; H01L 25/075; H01L 33/00

(52) U.S. Cl. CPC H01L 33/62; H01L 2933/0066; H01L 33/005; H01L 25/0753

(57) ABSTRACT

A method of producing a plurality of radiation-emitting components includes providing a composite with a plurality of connection carriers, wherein each connection carrier includes a light-transmissive matrix in which vias are arranged extending therethrough from a first main surface of the connection carrier to a second main surface of the connection carrier, and the connection carriers are spaced from each other by frames surrounding each connection carrier, arranging a radiation-emitting semiconductor chip on two vias, and separating the components by removing all or part of the frames.

### TECHNICAL FIELD

This disclosure relates to a method of producing a plurality of radiation-emitting components, a radiation-emitting component, a method of producing a connection carrier and a connection carrier.

### BACKGROUND

There is a need for an improved connection carrier and a radiation-emitting component with an improved connection carrier, as well as for a simplified method of producing a connection carrier and a simplified method of producing a radiation-emitting component with a connection carrier.

### SUMMARY

We provide a method of producing a plurality of radiation-emitting components including providing a composite with a plurality of connection carriers, wherein each connection carrier includes a light-transmissive matrix in which vias are arranged extending therethrough from a first main surface of the connection carrier to a second main surface of the connection carrier, and the connection carriers are spaced from each other by frames surrounding each connection carrier, arranging a radiation-emitting semiconductor chip on two vias, and separating the components by removing all or part of the frames.

We also provide a method of producing a plurality of spatially separated connection carriers including providing a composite with a plurality of connection carriers, wherein each connection carrier includes a light-transmissive matrix in which vias are arranged extending therethrough from a first main surface of the connection carrier to a second main surface of the connection carrier, and the connection carriers are spaced apart from each other by frames which completely surround each connection carrier, and separating the connection carrier by completely or partially removing the frames.

### BRIEF DESCRIPTION OF THE DRAWINGS

FIGS. 1 to 6 show schematic sectional views of process stages of a method of producing a plurality of spatially separated connection carriers according to an example.

FIG. 7 shows a schematic sectional view of a plurality of connection carriers according to an example.

FIGS. 8 to 9 show schematic sectional views of process stages of a method of manufacturing a radiation-emitting component according to an example.

FIGS. 10 to 13 show schematic top views of process stages of a method of manufacturing a radiation-emitting component according to a further example.

FIGS. 14 to 15 show schematic top views of process stages of a method of manufacturing radiation-emitting components according to a further example.

FIGS. 16 to 22 show schematic top view of radiation-emitting components according to various examples.

FIG. 23 shows a schematic perspective view of a module according to one example.

FIG. 24 shows an exemplary temperature distribution of an image area of a module.

FIG. 25 shows exemplary coordinates Cx and Cy of the color coordinate of light emitted from a radiation-emitting semiconductor chip as a function of temperature T.

FIG. 26 shows a schematic view of a video wall according to an example.

FIG. 27 shows a schematic view of a display according to an example.

### LIST OF REFERENCE SIGNS

1 semiconductor wafer
2 recess
3 post
4 frame
5 glass wafer
6 composite
7 light-transmissive matrix
8 Via
9 connection carrier
10 electrical connection pad
11, 11R, 11G, 11B, 11IR, 11L radiation-emitting semiconductor chip
12 radiation-emitting component
13 sensor
14 electronic control chip
15 mobile terminal
16 image area
17 substrate

### DETAILED DESCRIPTION

According to one example of the method of producing a plurality of radiation-emitting components, a composite is provided with a plurality of connection carriers.

Preferably, each connection carrier comprises a light-transmissive matrix. The light-transmissive matrix is particularly preferably transparent to visible light. The light-transmissive matrix preferably transmits 85% and particularly preferably at least 95% of the visible light. The light-transmissive matrix preferably comprises glass or is formed from glass.

Vias are preferably arranged in the light-transmissive matrix of each connection carrier, which extend through from a first main surface of the connection carrier to a second main surface of the connection carrier. Stated differently, the vias particularly preferably penetrate the light-transmissive matrix completely. The vias are preferably not covered by the matrix in the lateral direction at the first main surface and/or the second main surface of the connection carrier. Particularly preferably, the coefficient of thermal expansion of the matrix is matched to the coefficient of thermal expansion of the vias.

The vias can comprise different geometries. In particular, a cross-sectional area of the vias does not necessarily have to be round or circular. Via side walls can be perpendicular to the main surfaces of the connection carrier. Furthermore, it is also possible for the side walls to include an angle other than 90° with the main surfaces of the connection carrier. For example, the vias comprise a conical shape.

According to a further example, the connection carriers are spaced apart by frames. The frames particularly preferably completely surround each connection carrier. Particularly preferably, each connection carrier is surrounded by a frame. Particularly preferably, the frames of directly adjacent connection carriers are directly adjacent to one another. For example, the frames of directly adjacent connection carriers are formed in one piece in the composite. Preferably, the frames are formed from the same material as the vias.

The composite may be formed of a plurality of connection carriers and a plurality of frames, wherein preferably each connection carrier is surrounded by a frame.

The vias are particularly preferably electrically conductive. For example, the vias and/or the frames comprise a semiconductor material. Particularly preferably, the vias and/or the frames comprise silicon. The semiconductor material, for example, silicon is particularly preferably highly n-doped or highly p-doped. The vias are preferably provided for electrically contacting the radiation-emitting semiconductor chips. In particular, this is made possible by a highly doped semiconductor material such as highly doped silicon.

A radiation-emitting semiconductor chip may be arranged on two vias. Particularly preferably, the radiation-emitting semiconductor chip is electrically conductively connected with the two vias.

Furthermore, it is also possible for the radiation-emitting semiconductor chip to be arranged on only one or no vias. The electrical connection of the radiation-emitting semiconductor chip with a via can be created via a metallic layer.

For example, the radiation-emitting semiconductor chip is a light-emitting diode or a surface-emitting VCSEL (“vertical cavity surface-emitting laser”). The radiation-emitting semiconductor chip particularly preferably emits visible light, for example, red light, green light, ultraviolet light and/or blue light. Furthermore, it is also possible that the radiation-emitting semiconductor chip emits infrared light. In addition to a radiation-emitting semiconductor chip, an electronic semiconductor chip may also be used in the device to serve as a sensor. The sensor may be a photodiode, a camera, or a temperature sensor.

Particularly preferably, the components are singulated by removing all or part of the frames.

Providing the composite may comprise the steps described below. The composite thus produced comprises, in particular, a glass matrix as light-transmissive matrix and a semiconductor material for the frames and the vias. The composite may also be referred to as a glass semiconductor composite.

First, a semiconductor wafer is provided and patterned with recesses. For example, the recesses comprise a depth of 50 micrometers to 300 micrometers. Preferably, the recesses comprise a depth of 120 micrometers to 250 micrometers.

The semiconductor wafer can be patterned, for example, by etching using a photoresist mask. The recesses preferably start from a first main surface of the semiconductor wafer, but preferably do not completely cut through the semiconductor wafer. Preferably, posts are arranged in the recesses, starting from a second main surface of the semiconductor wafer opposite to the first main surface, which are continuously connected to each other by material of the semiconductor wafer. The posts particularly preferably form the subsequent vias. In a next step, the recesses are preferably filled with glass. Particularly preferably, the recesses are filled with glass by melting a glass wafer such that the composite is formed. The glass wafer is preferably applied to the first main surface of the semiconductor wafer and heated. The frames are advantageously used to stabilize the structured semiconductor wafer during the filling of the recesses with glass.

The composite may be thinned to form the plurality of connection carriers. Preferably, the composite is thinned starting from the second main surface. Prior to thinning the composite starting from the second main surface, the composite may also be thinned starting from the first main surface, for example, by a thickness of about 50 microns. After thinning, the composite has a thickness of 80 micrometers to 120 micrometers, for example. In this method, preferably the material of the semiconductor wafer that continuously bonds the posts together is completely removed. This preferably results in a surface formed by the matrix and the vias. The composite now preferably has two opposing main surfaces, each of which is formed in part by the matrix and in part by the vias.

The two main surfaces of the composite may be polished after thinning, for example, by a chemical-mechanical or dry polishing process. A chemical-mechanical polishing process can be used to adjust a topography between the matrix and the vias in a desired manner. For example, the vias can be recessed relative to the matrix.

Electrical connection pads may be arranged on the vias. Particularly preferably, an electrical connection pad is arranged on each via. The electrical connection pads are particularly preferably in direct contact with the vias. Particularly preferably, the electrical connection pads completely cover the vias. For example, the electrical connection pads are formed from a metal or comprise a metal. The electrical connection pads may comprise gold or be formed from gold.

The frames may be completely or partially removed by etching. Compared to sawing or laser cutting, this has the advantage that connection carriers with comparatively small dimensions can also be separated from one another. For example, the connection carriers have an edge length of 120 micrometers to 250 micrometers.

Etching can be anisotropic etching or isotropic etching. In isotropic etching, material removal is usually only slightly directional. Preferably, material removal in isotropic etching occurs equally in all spatial directions. Isotropic etching can be achieved by a gas such as XeF₂, or wet-chemically by a liquid such as KOH or NaOH. The ablated material is preferentially transferred to the gas phase during isotropic etching in a gas.

In anisotropic etching, on the other hand, material removal is usually directional, i.e., along a preferred direction. Anisotropic etching can be achieved using a plasma such as SF₆.

Particularly preferably, the electrical connection pads are arranged on the vias before etching. The electrical connection pads each preferably completely cover the vias. In this example, the frames are preferably completely or partially removed after application of the electrical connection pads by isotropic etching with the aid of a gas or a liquid. Advantageously, no additional lithographic mask is used to cover the vias. Rather, the electrical connection pads on the vias advantageously serve to protect the vias from the gas or liquid. This simplifies the manufacturing process.

The lateral surfaces of the connection carriers that may be formed by the complete or partial removal of the frames may preferably be formed entirely from the matrix. In other words, in this example, the vias are entirely located in a volume region of the matrix in the lateral direction. Isotropic etching can be performed, for example, in a gas such as XeF₂. A liquid may also be suitable for isotropic etching. The matrix is preferably essentially inert to the gas or liquid.

As an alternative to isotropic etching with the aid of a gas or liquid, anisotropic etching with the aid of a plasma can also be used for complete or partial removal of the frames. In the anisotropic etching process, a mask is particularly preferred. The mask preferably covers the vias such that the mask protects the vias from the plasma. The frames, on the other hand, are freely accessible so that they can be removed by the plasma. The matrix is preferably essentially inert to the plasma.

Vias can advantageously be formed that partially form the side surfaces of the finished connection carriers. In other words, the material of the vias is continuously bonded to the material of the frames in the composite prior to separation. The anisotropic etching process creates the side surface of the connection carrier between the vias and the frames, respectively. This example has the advantage that the vias can be arranged directly at the edge of the connection carriers so that a particularly compact formation of the finished radiation-emitting components with the connection carriers can be achieved.

For anisotropic etching, a so-called Bosch process can be used, for example. In a Bosch process, a dry etching process is usually alternated with a passivation step. In the dry etching process, the material to be removed is removed, usually isotropically. After a certain amount of material has been removed, a passivation step applies a passivation layer to the surface exposed by the dry etching process. This is followed by a further material removal, again usually isotropic, by another dry etching process. The dry etching process and the passivation step are carried out alternately until the material is cut through. In this way, a lateral surface with isolation traces characteristic of the Bosch process is produced. The isolation traces have, for example, indentations or sawtooth structures as structural elements. The indentations can be shell-shaped. In particular, the isolation traces generated by the Bosch process are usually formed regularly, i.e., identical or similar structural elements adjoin one another in a regular sequence. As described above, the isolation traces are typical for the Bosch process so that it can be proven on the finished connection carrier or on the finished component that a Bosch process was carried out for separation.

In the following, a method of manufacturing a plurality of connection carriers is described in more detail, wherein the connection carriers are preferably spatially separated from each other. All features and examples described in connection with the method of producing a plurality of radiation-emitting components can also be formed in the method of producing a plurality of spatially separated connection carriers, and vice versa.

The method of manufacturing a plurality of connection carriers differs from the method of manufacturing a plurality of radiation-emitting components in particular in that no radiation-emitting semiconductor chips are used in the former. For example, a plurality of connection carriers can first be fabricated using the described method, which are subsequently equipped with semiconductor chips. Furthermore, it is also possible that the radiation-emitting semiconductor chips are applied to the connection carriers during their manufacturing process, whereby the complete or partial removal of the frames results in a plurality of radiation-emitting components.

According to one example of the method of producing a plurality of spatially separated connection carriers, a composite comprising a plurality of connection carriers is first provided. Each connection carrier preferably has a light-transmissive matrix in which vias are disposed. The vias preferably extend through from a first main surface of the connection carrier to a second main surface of the connection carrier. Further, the composite preferably comprises a plurality of frames. The connection carriers are preferably spaced apart from each other by the frames. Each connection carrier is preferably completely surrounded by a frame. The connection carriers may be singulated by removing all or part of the frames.

With the method described here of producing a large number of connection carriers and/or radiation-emitting components, it is advantageously possible to efficiently produce connection carriers or components with connection carriers, in which the largest possible volume fraction is formed from the light-transmissive matrix. This increases the efficiency of a radiation-emitting component with this connection carrier.

The method described herein can be used to produce a plurality of connection carriers, which are preferably spatially separated from one another. Features and examples described in connection with the method of producing a plurality of connection carriers can also be formed in the connection carrier and vice versa.

The connection carrier is provided to electrically conductively connect the radiation-emitting semiconductor chip to a connection board. The connection carrier is intended to form part of the radiation-emitting component. All examples and features described here in connection with the radiation-emitting component can also be implemented in the connection carrier and vice versa.

The connection carrier may comprise a light-transmissive matrix in which vias are arranged. The vias preferably extend through from a first main surface of the connection carrier to a second main surface of the connection carrier, the second main surface being opposite the first main surface. Side surfaces of the connection carrier are particularly preferably formed by the light transmissive matrix and/or the vias. In other words, the side surfaces of the connection carrier preferably do not comprise any other material than the material of the matrix and/or the material of the vias.

The vias are preferably electrically insulated from one another in the connection carrier by the light-transmissive matrix. The matrix advantageously has a comparatively high dielectric constant so that effective electrical isolation of the vias from one another is possible with the aid of the matrix.

The method described above can be used to produce a radiation-emitting component. The radiation-emitting component is described in more detail below. Features and examples described herein in connection with the method of producing a plurality of radiation-emitting components may also be formed in the radiation-emitting component, and vice versa.

The radiation-emitting component may comprise a connection carrier featuring a light transmissive matrix. Preferably, vias are disposed in the light-transmissive matrix and extend through from a first main surface of the connection carrier to a second main surface of the connection carrier. Side surfaces of the connection carrier are preferably formed by the light-transmissive matrix and/or the vias. Furthermore, the radiation-emitting component particularly preferably comprises at least one radiation-emitting semiconductor chip.

The radiation-emitting semiconductor chip may have a polygonal, for example, triangular, rectangular, or hexagonal shape in plan view. It is also possible for the radiation-emitting semiconductor chip to have a round, for example, circular shape in plan view.

The connection carrier may also have a polygonal shape such as triangular, rectangular or hexagonal in plan view. If the connection carrier has a polygonal shape such as a rectangular shape in plan view, the corners may be rounded. It is also possible for the connection carrier to have a round shape such as a circular shape in plan view.

The radiation-emitting semiconductor chip can be electrically contacted via the second main surface of the connection carrier, particularly preferably with the aid of the two vias. The second main surface of the connection carrier is opposite the first main surface of the connection carrier on which the semiconductor chips are arranged.

The radiation-emitting component may comprise at least one radiation-emitting semiconductor chip that emits electromagnetic radiation from the visible spectral range. Furthermore, it is possible that the radiation-emitting semiconductor chip emits infrared radiation. The radiation-emitting semiconductor chip may also be a VCSEL.

Particularly preferably, the radiation-emitting component comprises at least one red emitting semiconductor chip, at least one green emitting semiconductor chip, and at least one blue emitting semiconductor chip. In other words, the radiation-emitting component preferably comprises at least three radiation-emitting semiconductor chips, one of which emits red light, one of which emits green light, and one of which emits blue light.

The radiation-emitting component may comprise at least one red-emitting semiconductor chip and at least one yellow-emitting semiconductor chip. Such components are particularly suitable for applications in the automotive sector, for example, in turn signals and/or tail lights.

The radiation-emitting component may comprise a radiation-emitting semiconductor chip that emits electromagnetic radiation from the infrared spectral range during operation. Particularly preferably, in this example, the radiation-emitting component further comprises at least one red-emitting semiconductor chip, at least one green-emitting semiconductor chip, and at least one blue-emitting semiconductor chip.

Such a radiation-emitting component is particularly suitable for use in a display or video wall to form one or more pixels. During operation of the display or video wall, the infrared semiconductor chip emits electromagnetic radiation from the infrared spectral range, which provides, for example, information such as QR codes or other 2D codes. This information is intended, for example, to be recognized by a camera outside the display or video wall.

Furthermore, the information may also correspond to a data exchange protocol so that it can be received and read by a data receiver such as a smartphone. Particularly preferably, in this example, the radiation-emitting component comprises a sensor suitable for receiving infrared radiation. In this way, it is possible for the display or video wall to also receive information from outside. Such a display or video wall can thus exchange information with smartphones of passers-by, for example, for advertising purposes.

The term “video wall” particularly refers to an image display device with pixels in which a distance between two directly adjacent pixels is at least 500 micrometers. Furthermore, the video wall is generally modularly constructed from a plurality of modules. The video wall is used, for example, for image display at large events.

The term “display” as used herein refers in particular to an image display device in which a distance between two directly adjacent pixels is at most 500 micrometers. The display is used in particular in televisions, computer monitors, smart watches and/or smart mobile phones for image display.

According to a further example of the radiation-emitting component, an electrical connection pad is applied to each via, which is electrically conductively connected to the semiconductor chip. In this example, the semiconductor chip preferably covers each electrical connection pad, particularly preferably completely.

The connection carrier may have a hexagonal shape or a rectangular shape in plan view. Particularly preferably, the hexagonal shape is a regular hexagon.

The radiation-emitting component may have a plurality of semiconductor chips. The semiconductor chips and the connection carrier have a rectangular shape in plan view. In this example, the semiconductor chips are particularly preferably arranged in rows and/or columns.

The connection carrier may have a hexagonal shape in plan view. In addition, the radiation-emitting component preferably comprises a plurality of semiconductor chips each having a side surface arranged parallel to a side surface of the connection carrier. In this example, the semiconductor chips may have a rectangular or triangular shape in plan view.

The radiation-emitting component may comprise at least one electronic semiconductor chip. The electronic semiconductor chip may be a sensor. For example, in operation, the sensor detects infrared radiation, a temperature such as an ambient temperature, or a brightness such as of the environment. Furthermore, the electronic semiconductor chip may be a sensor suitable for image acquisition such as a CCD sensor or a CMOS sensor.

The radiation-emitting component may comprise a sensor that detects the temperature during operation. Preferably, the sensor detects the temperature of the component. If the temperature of the radiation-emitting component is known, this opens up the possibility of compensating for a chromaticity shift in the color of the electromagnetic radiation of the radiation-emitting semiconductor chips due to temperature differences.

The radiation-emitting component preferably comprises an electronic control chip used to drive at least one of the semiconductor chips of the radiation-emitting component. For example, the control chip comprises an integrated circuit. Preferably, the control chip is arranged to drive at least one and preferably all of the radiation-emitting semiconductor chips by pulse-width modulated signals. Pulse-width modulated signals are generally suitable for dynamically adapting the color coordinate of the light emitted by the radiation-emitting semiconductor chips to a predetermined value. In this example, it is advantageously possible to integrate an additional electronic high-performance chip into the component or to provide the drive chip with additional high-performance electronics without changing the color of the light emitted by the radiation-emitting semiconductor chips due to the high temperatures generated during operation.

The radiation-emitting component described here is particularly suitable for use in a video wall or in a display. In particular, a radiation-emitting component with a red-emitting, a green-emitting and a blue-emitting semiconductor chip can advantageously be used as a particularly compact RGB light source in the video wall or display. For example, the RGB light source may be part of at least one pixel of the video wall or display. In addition, the connection carrier described herein has a light-transmissive matrix that forms a particularly large volume portion of the connection carrier.

The radiation-emitting component may comprise a sensor that detects the brightness of the environment during operation. Particularly preferably, the radiation-emitting component in this example further comprises at least one semiconductor chip that emits red during operation, at least one semiconductor chip that emits green during operation, and at least one semiconductor chip that emits blue during operation. Such a radiation-emitting component is particularly suitable for use in a display or video wall for forming one or more pixels. With the aid of the sensor, which detects the brightness of the environment in operation, it is advantageously possible to adjust the brightness of the radiation of the radiation-emitting semiconductor chips locally and dynamically such that a recognizable image of the display or the video wall is present at every point, even if different ambient brightnesses are present in different areas of the display or the video wall.

The component may comprise a VCSEL. Particularly preferably, in this example, the radiation-emitting component further comprises at least one semiconductor chip emitting red during operation, at least one semiconductor chip emitting green during operation, and at least one semiconductor chip emitting blue during operation. Such a radiation-emitting component is particularly suitable for use in a display or video wall that is further equipped with a 3D recognition device. In this way, information can be generated as to whether objects, for example, visitors are located in front of the display or video wall.

The component may have a CCD sensor and/or a CMOS sensor. The CCD sensor and/or the CMOS sensor preferably serve for image acquisition. Particularly preferably, in this example, the radiation-emitting component further comprises at least one semiconductor chip that emits red during operation, at least one semiconductor chip that emits green during operation, and at least one semiconductor chip that emits blue during operation. Such a component is particularly suitable for use in a display or video wall having a curved image surface for forming one or more pixels. For example, the curved image surface has the shape of a segment of a spherical surface. In particular, in combination with the curved image surface of the display or video wall, it is possible to form a compound eye as a camera of the display or video wall by the CCD sensors and/or CMOS sensors.

The radiation-emitting component described here is particularly suitable for use in a module for image display. For example, the module is part of a display or a video wall. Features and examples described herein only in connection with the radiation-emitting component can also be implemented in the module and vice versa.

The module may comprise a plurality of radiation-emitting components. The radiation-emitting components are preferably arranged on a first main surface of a substrate and adapted to form pixels for image display.

The module may comprise an electronic control chip on a second main surface of the substrate opposite the first main surface. Preferably, the control chip is used to control the radiation-emitting semiconductor chips of at least one component of the module. Preferably, the control chip is adapted to drive the radiation-emitting semiconductor chips of all components. For example, the control chip comprises an integrated circuit. Preferably, the control chip is arranged to drive at least one and preferably all of the radiation-emitting semiconductor chips of the module using pulse-width modulated signals. Pulse-width modulated signals are generally suitable for dynamically adapting the color coordinate of the light emitted by the radiation-emitting semiconductor chips to a predetermined value. With this example, it is advantageously possible to integrate an additional electronic high-performance chip into the module or to provide the control chip with additional high-performance electronics without changing the color of the light of the radiation-emitting semiconductor chips due to the high temperatures generated during operation.

Advantages and further examples of our two methods, the conversion element and the radiation-emitting component are explained in more detail below with reference to the figures.

Elements that are identical, similar or have the same effect are given the same reference signs in the figures. The figures and the proportions of the elements shown in the figures are not to be regarded as true to scale. Rather, individual elements, in particular layer thicknesses, may be shown exaggeratedly large for better representability and/or understanding.

In the method according to the example of FIGS. 1 to 6, a semiconductor wafer 1 is first provided (FIG. 1). The semiconductor wafer 1 is formed, for example, from highly doped silicon.

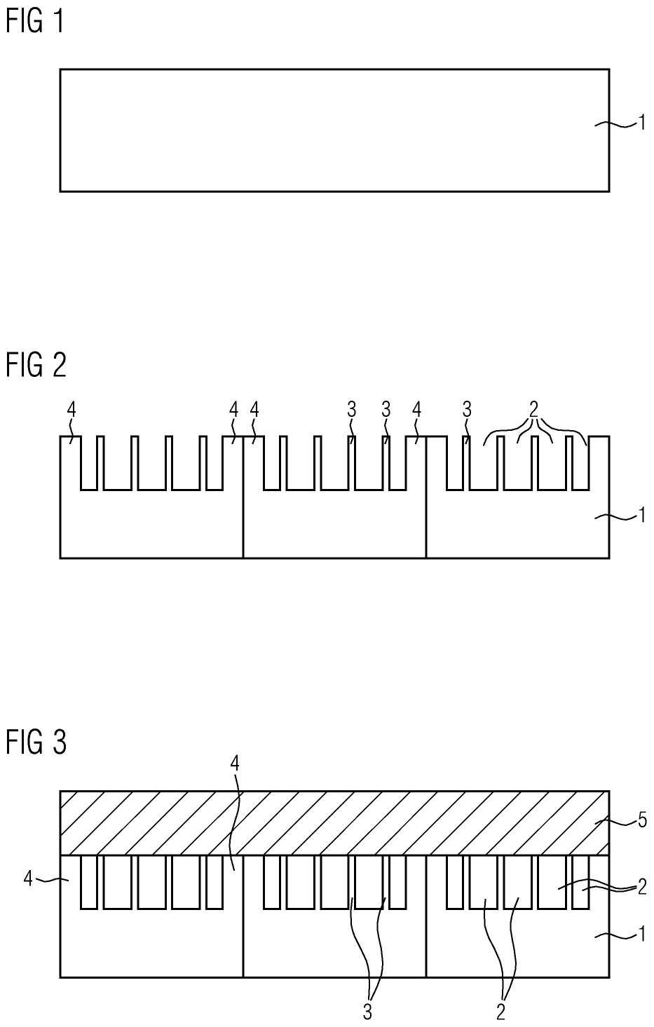

Starting from a first main surface, the semiconductor wafer 1 is structured with recesses 2 in which posts 3 are arranged. For example, the recesses 2 have a depth of about 200 micrometers. In addition, the semiconductor wafer 1 has frames 4, each of which surrounds a plurality of posts 3 (FIG. 2). The semiconductor wafer 1 can be patterned, for example, using a lithographic mask and an etching process.

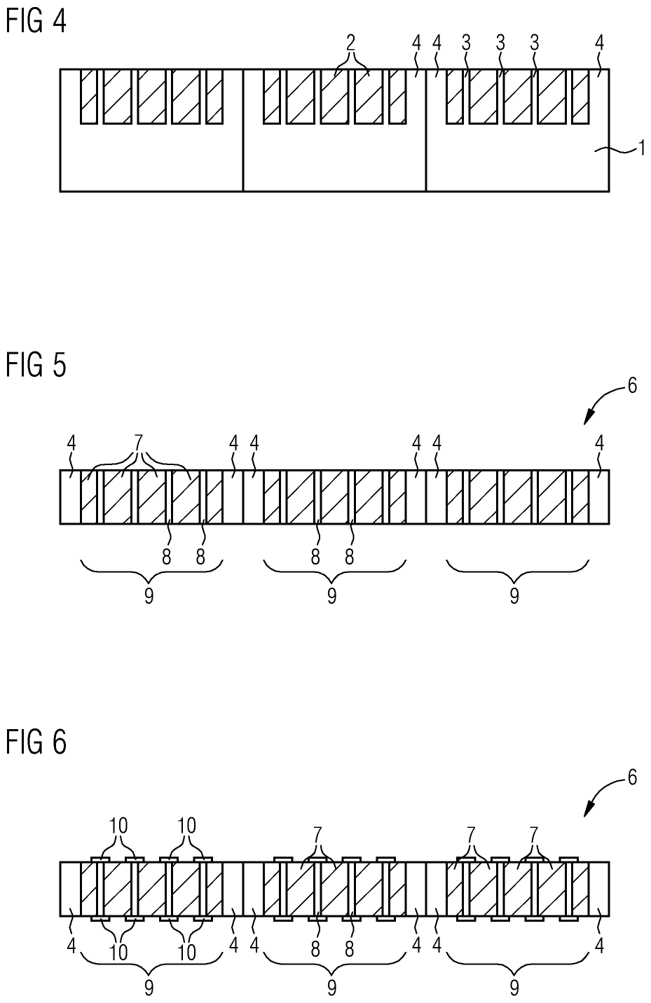

In the next step, which is shown schematically in FIGS. 3 and 4, the recesses 2 are filled with glass. For this purpose, a glass wafer 5 is applied to the structured first main surface of the semiconductor wafer 1 under vacuum (FIG. 3) and melted, for example, by heating. The liquid glass fills the recesses 2, especially preferably completely (FIG. 4).

In a next step, the semiconductor wafer 1 is thinned from its second main surface, which is opposite to the first main surface (FIG. 5). The thinning removes the material of the semiconductor wafer 1 which, starting from the second main surface of the semiconductor wafer 1, connects the posts 3 to each other and forms a bottom surface of the recesses 2. After thinning, the glass is presently freely accessible.

Thinning results in a composite 6 comprising a light-transmissive matrix 7, presently formed of glass, and a plurality of vias 8 formed of the material of the semiconductor wafer 1. Further, the composite 6 comprises a plurality of frames 4, each of which completely surrounds a plurality of vias 8. In other words, the composite 6 comprises a plurality of connection carriers 9 spaced apart from each other by circumferential frames 4. The frames 4 here have the same material as the vias 8, namely highly doped silicon. After thinning, the composite 6 has a thickness of approximately 100 micrometers.

In a next step, an electrical connection pad 10 is arranged on each via 8 (FIG. 6). The electrical connection pads 10 are positioned at a distance from each other. Each electrical connection pad 10 covers a via 8 completely. The electrical connection pads 10 are particularly preferably metallic. For example, the electrical connection pads 10 are made of gold. The electrical connection pads 10 can also be applied at least partially before thinning.

In a next step, the connection carriers 9 are separated by completely or partially removing the frames 4 from the composite 6, for example, by anisotropic etching in a plasma, isotropic etching in a gas or a liquid. The vias 8 are protected from the plasma by the electrical connection pads 10 so that a mask can advantageously be dispensed with.

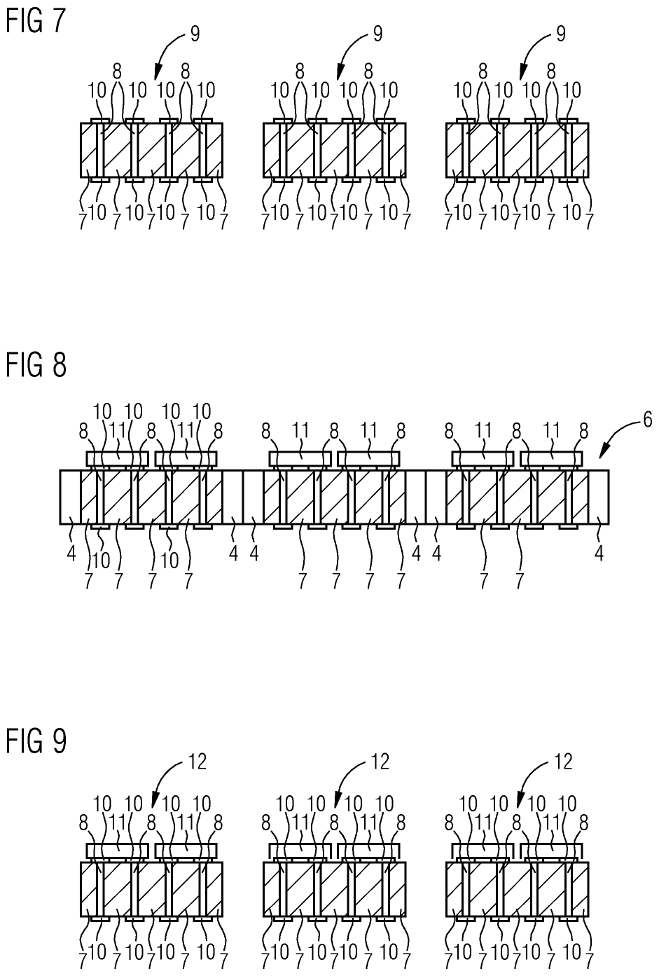

FIG. 7 shows a plurality of spatially separated finished connection carriers 9 that can be produced by the method described in FIGS. 1 to 6.

The connection carriers 9 according to the example of FIG. 7 have a light-transmissive matrix 7, which in this example is formed from glass. Within the light-transmissive matrix 7 a plurality of vias 8 is arranged, which in this example comprise a highly doped silicon. The vias 8 extend from a first main surface of the connection carrier 9 to a second main surface of the connection carrier 9. The vias 8 can be flush with the matrix 7 at the two main surfaces. Furthermore, it is also possible for the vias 8 to be set back relative to the matrix 7 on at least one main surface (not shown here). The vias 8 are electrically insulated from each other by the matrix 7.

Electrical connection pads 10, for example, made of gold, are arranged on the vias 8. The electrical connection pads 10 completely cover the vias 8. Side surfaces of the connection carriers 9, which are arranged between their first main surface and the second main surface, are formed completely from the light-transmissive matrix 7. For example, the connection carriers 9 have an area of approximately 140 micrometers by 210 micrometers.

In the method of the example according to FIGS. 8 and 9, a composite 6 is first created as already described with reference to FIGS. 1 to 6.

Radiation-emitting semiconductor chips 11 are applied to the electrical connection pads 10 of the composite 6 (FIG. 8). The radiation-emitting semiconductor chips 11 are electrically connected to the electrical connection pads 10 of the first main surface of the composite 6 so that they can later be electrically contacted externally via the electrical connection pads 10 on the second main surface of the composite 6. The radiation-emitting semiconductor chips 11 can also be applied to the composite 6 before thinning.

In a next step, the radiation-emitting components 12 are separated by completely or partially removing the frames 4, for example, by isotropic etching in a gas (FIG. 9).

In the method according to the example of FIGS. 10 to 13, a structured semiconductor wafer 1 is again provided. This has a plurality of frames 4, each of which surrounds a plurality of posts 3 arranged in recesses 2 (FIG. 10).

In a next step, a light-transmissive matrix 7, in this example, glass is filled into the recesses 2 between the posts 3 within each frame 4. Electrical connection pads 10 are applied to the vias 8 (FIG. 11).

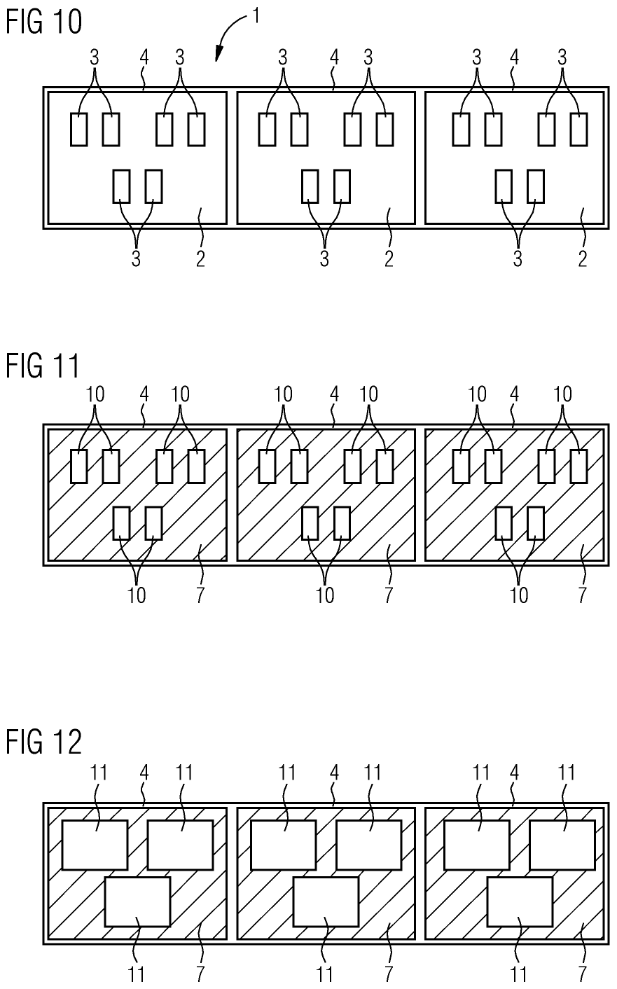

Then, a radiation-emitting semiconductor chip 11 is applied to each two electrical connection pads 10, as shown in FIG. 12. The semiconductor chips 11 are electrically connected to the electrical connection pads 10.

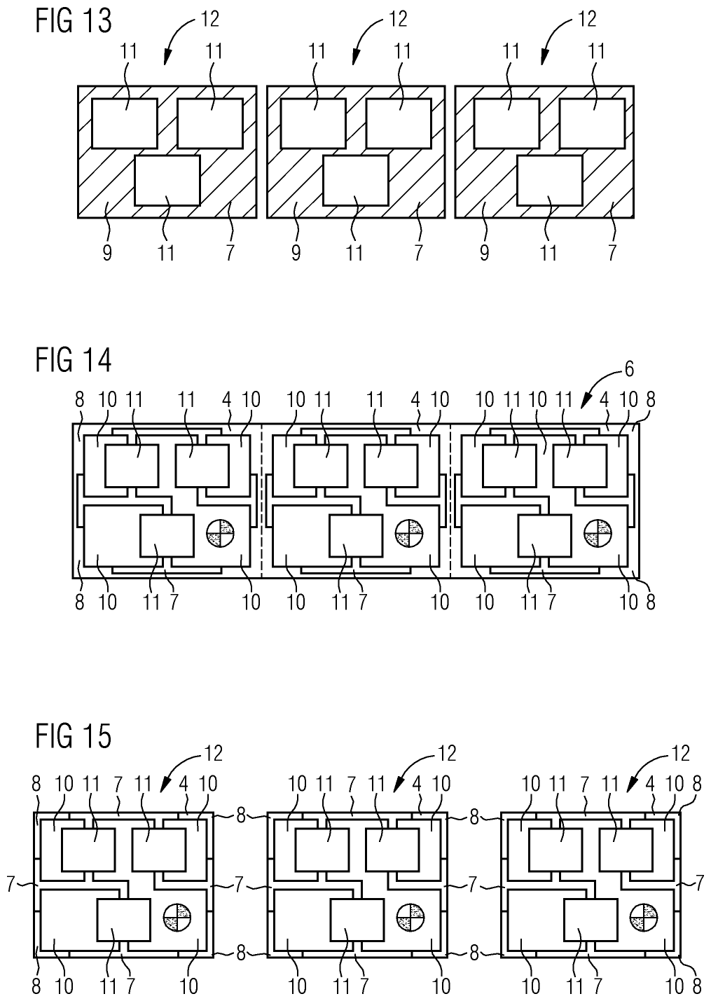

In a next step, the frames 4 are completely or partially removed so that the radiation-emitting components 12 are separated (FIG. 13). The frames 4 are removed, for example, by isotropic etching. The radiation emitting components 12 have an area of approximately 140 micrometers by 175 micrometers, for example.

In the method according to the example of FIGS. 14 and 15, a composite 6 with a plurality of connection carriers 9 is again provided (FIG. 14). Each connection carrier 9 has a plurality of vias 8, which are completely covered by electrical connection pads 10. Radiation-emitting semiconductor chips 11 are applied to the electrical connection pads 10. The electrical connection pads 10 are electrically insulated from one another by a light-transmissive matrix 7. The light-transmissive matrix 7 is made of glass. In addition, each connection carrier 9 is surrounded by a frame 4. In each example, two frames 4 that run around directly adjacent connection carriers are formed to be directly contiguous. In addition, each frame 4 is formed contiguously with vias 8 of the connection carrier 9 around which the frame 4 runs. At least some vias 8 within a frame 4 are formed integrally with the frame 4 at this stage of the process.

The radiation-emitting components 12 are separated in a next step, in this example by anisotropic etching, for example, with a Bosch process (FIG. 15). During separation, the frames 4 are completely or partially removed by anisotropic etching, for example, using a Bosch process. In this method, the vias 8 are retained and each form part of the side surface of the singulated connection carriers 9. The components 12 have an area of approximately 160 micrometers by 205 micrometers, for example.

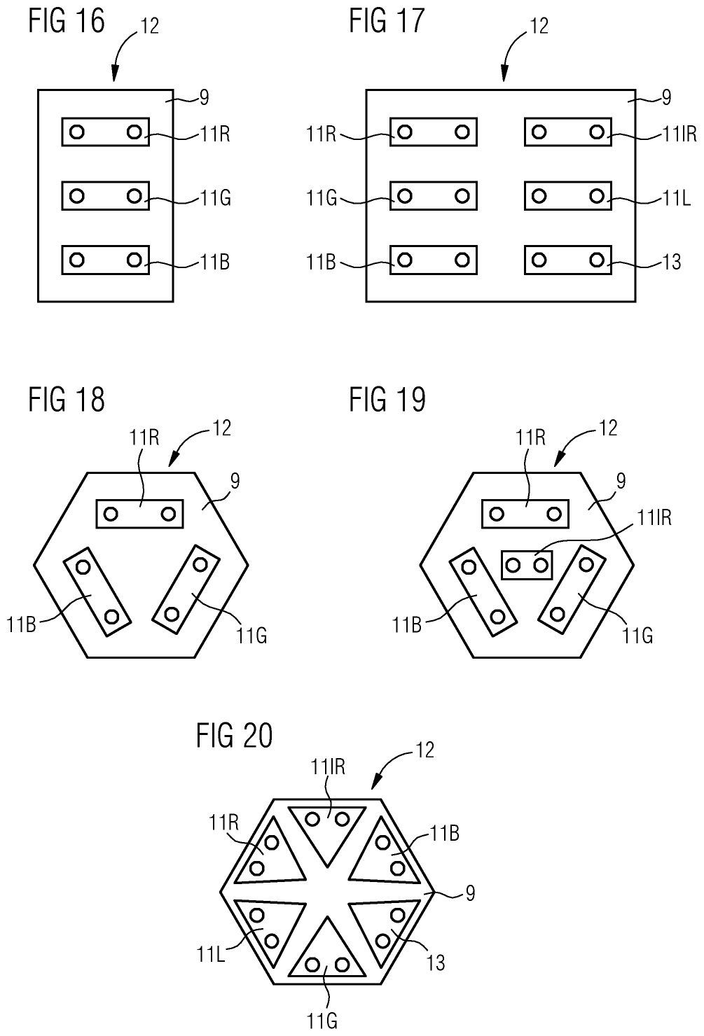

The radiation-emitting components 12 according to the example of FIG. 16 comprises a connection carrier 9 having a rectangular shape in plan view. Further, the radiation-emitting component 12 according to the example of FIG. 16 has three radiation emitting semiconductor chips 11R, 11G, 11B, one of which emits red light, one of which emits green light, and one of which emits blue light in operation. The radiation-emitting semiconductor chips 11R 11G, 11B have a rectangular shape in plan view, as does the connection carrier 9. The semiconductor chips 11R, 11G, 11B are arranged in a column.

The radiation-emitting component 12 according to the example of FIG. 17, in contrast to the radiation-emitting component 12 according to FIG. 16, has an infrared emitting semiconductor chip 11IR, a VCSEL 11L, and a sensor 13 in addition to the red emitting semiconductor chip 11R, the green emitting semiconductor chip 11G, and the blue emitting semiconductor chip 11B. For example, the sensor 13 is adapted to detect infrared radiation. By the infrared-emitting semiconductor chip 11IR, for example, information that is not in the visible range can be provided. In this example, the radiation-emitting semiconductor chips 11R, 11G, 11B that emit light from the visible range are arranged in a common column. The infrared emitting semiconductor chip 11IR, the VCSEL 11L, and the sensor 13 are arranged in a directly adjacent column.

The component 12 according to the example of FIG. 18, in contrast to the radiation-emitting component 12 of FIG. 16, comprises a connection carrier 9 having a hexagonal shape in plan view. The red-emitting semiconductor chip 11R, the green-emitting semiconductor chip 11G, and the blue-emitting semiconductor chip 11B have a rectangular shape in this example. The radiation-emitting semiconductor chips 11R, 11G, 11B are each arranged with a side surface parallel to a side surface of the connection carrier 9.

The radiation-emitting component 12 according to the example of FIG. 19 has, in contrast to the radiation-emitting component 12 according to FIG. 18, a further semiconductor chip 11IR that emits infrared radiation during operation. The semiconductor chip 11IR emitting infrared radiation is positioned centrally on the connection carrier 9.

The radiation-emitting component 12 according to the example of FIG. 20, like the radiation-emitting components 12 according to the examples of FIGS. 18 and 19, has a connection carrier 9 with a hexagonal shape in plan view. However, unlike the examples of FIGS. 18 and 19, the semiconductor chips 11R, 11G, 11B, 11L, 11IR 13 of the component 12 according to the example of FIG. 20 have a triangular shape. In this example, the semiconductor chips 11R, 11G, 11B, 11L, 11IR are each arranged with a side surface parallel to a side surface of the connection carrier 9. The use of semiconductor chips 11R, 11G, 11B, 11L, 11IR, 13 with a triangular shape in plan view and a connection carrier 9 with a hexagonal shape in plan view permits particularly good utilization of the area of the connection carrier 9.

The radiation-emitting component shown in FIG. 20 has a red emitting semiconductor chip 11R, a blue emitting semiconductor chip 11B and a green emitting semiconductor chip 11G. An infrared-emitting semiconductor chip 11IR, a sensor 13 or a VCSEL 11L is arranged between two semiconductor chips 11R, 11G, 11B hat emit visible light.

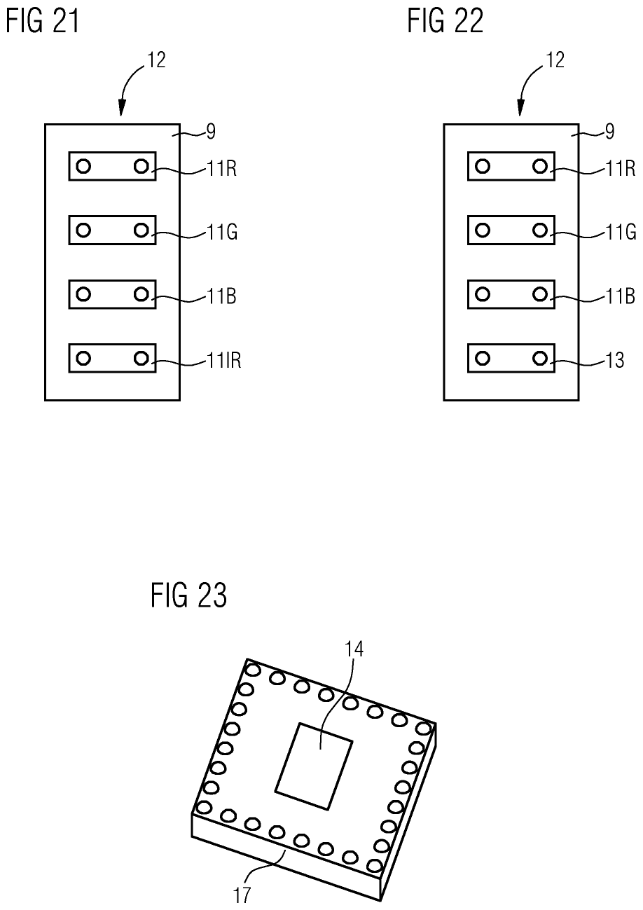

The component 12 according to the example of FIG. 21, in contrast to the radiation-emitting component 12 according to FIG. 16, has, in addition to a semiconductor chip 11R which emits red radiation during operation, a semiconductor chip 11B which emits green radiation during operation, and a semiconductor chip 11B that emits blue radiation during operation, a radiation-emitting semiconductor chip 11IR that emits infrared radiation during operation. The radiation-emitting semiconductor chips 11R, 11G, 11B, 11IR are arranged in a row.

The radiation-emitting component 12 according to the example of FIG. 21 has a different design from the radiation-emitting component 12 according to FIG. 19, while the radiation-emitting semiconductor chips 11R, 11G, 11B, 11IR have the same design. By the radiation-emitting semiconductor chip 11IR emitting infrared electromagnetic radiation, information invisible to the human eye can be provided as an advantage.

The component 12 according to the example of FIG. 22, in contrast to the component 12 according to FIG. 21, has, instead of the radiation-emitting semiconductor chip 11IR which emits infrared radiation, a sensor 13 which detects the brightness of the environment during operation.

The module according to the example of FIG. 23 has a plurality of radiation-emitting components 12 deposited on a first main surface of a substrate 17. The radiation-emitting components 12 are not visible in this example.

Preferably, the radiation-emitting component 12 comprises three radiation-emitting semiconductor chips 11R, 11G, 11B, one of which emits red light in operation, one of which emits green light in operation, and one of which emits blue light in operation. An electronic control chip 14 is centrally disposed on a second main surface of the substrate 17. Furthermore, the radiation-emitting components of the module according to the example of FIG. 23 each have a sensor 13 (not shown) that detects the temperature of the semiconductor chips 11R, 11G, 11B.

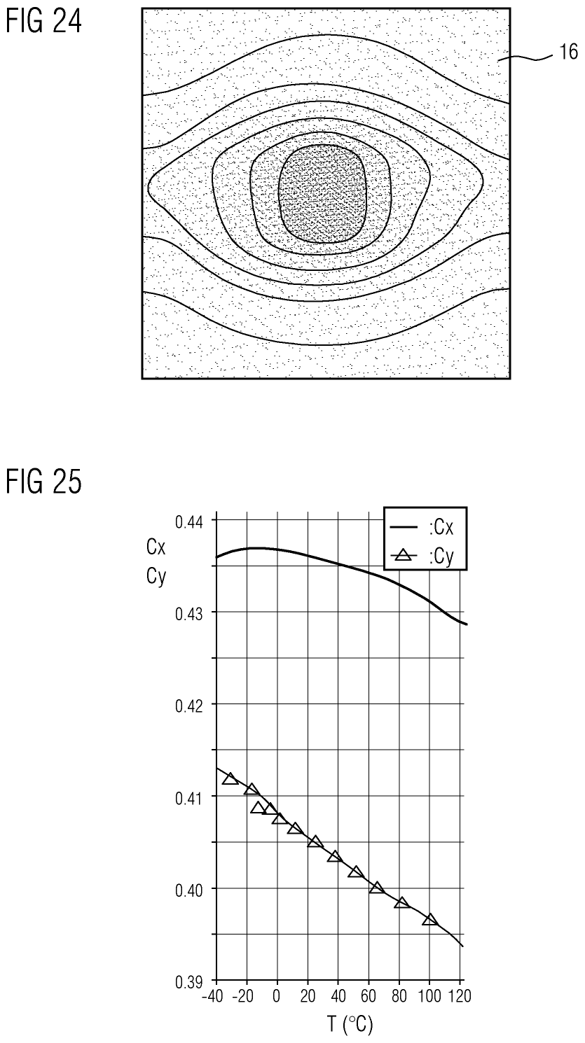

When the temperature of the radiation-emitting semiconductor chips 11R, 11G, 11B is increased, the color coordinates of the electromagnetic radiation emitted from the semiconductor chips 11R, 11G, 11B are generally shifted to lower values as the temperature increases. Such a shift is shown, for example, in FIG. 25. This results in an uneven temperature distribution over an image area 16 of the module as shown in FIG. 24.

In the module according to the example of FIG. 23, the temperature T is measured by the temperature sensor and the measured value is transmitted to the electronic control chip 14 on the rear side of the module. The electronic control chip 14 is adapted to drive the radiation emitting semiconductor chips 11R, 11G, 11B with pulse-width modulated signals during operation of the module so that the color coordinates of the light emitted from the radiation-emitting semiconductor chips 11R, 11G, 11B are adjusted to a desired value when the temperature of the radiation-emitting semiconductor chips 11R, 11G, 11B changes.

The video wall according to the example of FIG. 26 comprises a plurality of radiation-emitting components 12 as already described, for example, with reference to FIG. 16. Furthermore, the video wall according to the example of FIG. 26 comprises at least one radiation-emitting component 12 as already described with reference to FIG. 21. In other words, the video wall has at least one radiation-emitting component 12 having a semiconductor chip 11IR which emits infrared radiation during operation. The in operation red emitting, in operation green emitting and in operation blue emitting semiconductor chips 11R, 11G, 11B of the components 12 form present pixels of the video wall.

For example, the infrared radiation can be received by a mobile terminal 15 such as a smart portable phone so that it is possible to send suitable information from the video wall to the mobile terminal 15. For this purpose, the infrared radiation generally obeys an IR protocol.

Furthermore, it is possible that the video wall according to the example of FIG. 26 alternatively or additionally comprises a radiation-emitting component 12 as already described with reference to FIG. 17. Such a component 12 has, in particular, a VCSEL 11L which, together with a 3D detection, makes it possible to detect whether there are viewers in front of the video wall.

In addition, the component 12 shown in FIG. 17 has an infrared radiation emitting semiconductor chip 11IR and a sensor 13 that can detect infrared radiation. This enables the video wall to communicate with a mobile terminal 15 by infrared radiation.

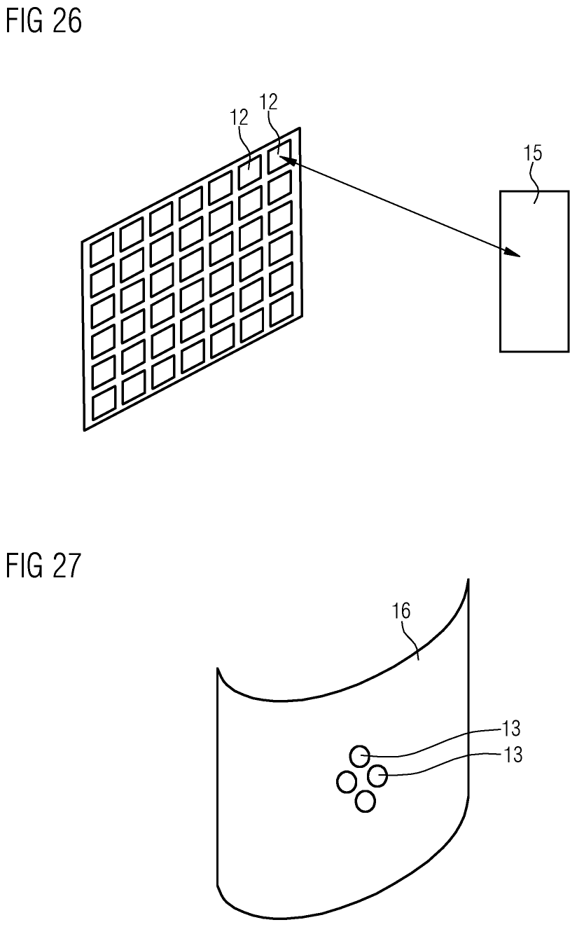

The display according to the example of FIG. 27 has a curved image area 16. The display has a plurality of radiation-emitting components 12, of which only the components 12 in a center of the image area 16 have, in addition to a red-emitting semiconductor chip 11R, a green-emitting semiconductor chip 11G and a blue-emitting semiconductor chip 11B for forming pixels, a sensor 13 suitable for image recording such as a CCD sensor or a CMOS sensor. The radiation-emitting semiconductor chips 11R, 11G, 11B are not shown in FIG. 27 for clarity, but only the sensors 13 forming a compound eye in the center of the image area.

This application claims priority of DE 102018128570.1, the content of which is hereby incorporated by reference.

Our methods, components and carriers are not limited by the description based on the examples. Rather, this disclosure encompasses any new feature as well as any combination of features that in particular includes any combination of features in the appended claims, even if the feature or combination itself is not explicitly stated in the claims or examples.

1-19. (canceled)

20. A method of producing a plurality of radiation-emitting components comprising:
providing a composite with a plurality of connection carriers, wherein
each connection carrier comprises a light-transmissive matrix in which vias are arranged extending therethrough from a first main surface of the connection carrier to a second main surface of the connection carrier, and
the connection carriers are spaced from each other by frames surrounding each connection carrier,
arranging a radiation-emitting semiconductor chip on two vias, and
separating the components by removing all or part of the frames.

21. The method according to claim 20, wherein providing the composite comprises steps:
providing a semiconductor wafer,
structuring the semiconductor wafer with recesses starting from a first main surface, wherein posts are arranged in the recesses, and
filling the recesses with glass by melting a glass wafer so that the composite is formed.

22. The method according to claim 21, wherein the composite is thinned to form the plurality of connection carriers.

23. The method according to claim 22, wherein electrical connection pads are arranged on the vias.

24. The method according to claim 20, wherein the frames are completely or partially removed by etching.

25. The method according to claim 20, wherein
electrical connection pads are arranged on the via before etching,
the frames are completely or partially removed by isotropic etching with a gas or liquid, wherein no additional lithographic mask is used, and
side surfaces of the connection carriers are formed entirely from the matrix.

26. The method according to claim 20, wherein
the frames are completely or partially removed by anisotropic etching using a mask, and
the vias partially form the side surfaces of the connection carriers.

27. A method of producing a plurality of spatially separated connection carriers comprising:
providing a composite with a plurality of connection carriers, wherein
each connection carrier comprises a light-transmissive matrix in which vias are arranged extending therethrough from a first main surface of the connection carrier to a second main surface of the connection carrier, and
the connection carriers are spaced apart from each other by frames which completely surround each connection carrier, and
separating the connection carrier by completely or partially removing the frames.
